(19) United States
(12) Patent Application Publication
(10) Pub. No.: US 2026/0130254 A1
(43) Pub. Date: May 7, 2026

(54) SMART IC SUBSTRATE, SMART IC MODULE, AND IC CARD COMPRISING SAME

(71) Applicants: LG INNOTEK CO., LTD., Seoul (KR); KOREA UNIVERSITY RESEARCH AND BUSINESS FOUNDATION, Seoul (KR)

(72) Inventors: Min Sung JO, Seoul (KR); Myoung Lae ROH, Seoul (KR); Tae Jin LEE, Seoul (KR); Seok Su SOHN, Seoul (KR); Hyun CHUNG, Seoul (KR); Tae Jin JANG, Seoul (KR)

(21) Appl. No.: 19/122,962

(22) PCT Filed: Oct. 6, 2023
(86) PCT No.: PCT/KR2023/015369

§ 371 Date: Apr. 21, 2025

(30) Foreign Application Priority Data
Oct. 21, 2022 (KR) 10-2022-0136444
Aug. 18, 2023 (KR) 10-2023-0108389

(51) Int. Cl. H10W 70/60; H10W 70/66; H10W 70/68; H10W 74/10; H10W 90/00

(52) U.S. Cl. CPC H10W 70/699; H10W 70/681; H10W 74/114; H10W 90/754; H10W 70/66

(57) ABSTRACT

A smart IC substrate according to an embodiment includes a substrate including a first surface and a second surface opposite to the first surface; a bonding layer disposed on the first surface; a metal layer disposed on the bonding layer; and a plating layer disposed on one surface of the metal layer, and wherein the metal layer includes an aluminum (Al)-copper (Cu) alloy or an aluminum (Al)-copper (Cu)-A alloy.

### TECHNICAL FIELD

An embodiment relates to a smart IC substrate, a smart IC module, and an IC card comprising same.

### BACKGROUND ART

An IC card is a plastic card with an integrated circuit chip embedded therein. The integrated circuit chip stores and processes information. The information is transmitted to a reader in a form of an electric signal.

The IC card is manufactured by inserting a smart IC module into a main body of the card.

The smart IC module is classified into a single type or a dual type depending on an arrangement of a metal layer. The single type has a metal layer and a plating layer disposed only on one surface of a substrate. The dual type has a metal layer and a plating layer disposed on both surfaces of the substrate.

In addition, the smart IC module is classified into a contact, contactless, hybrid, and combi card depending on an usage method of the card. The contact card transmits and receives information by physical contact. The contactless card transmits and receives information without physical contact. The hybrid card and the combi card include both the contact and contactless functions.

Accordingly, the smart IC module includes a contact surface and a bonding surface. The contact surface comes into contact with an external device. A chip is disposed on the bonding surface. The bonding surface is inserted inside of the card body.

The chip disposed on the bonding surface and the metal layer disposed on the contact surface are electrically connected by wire bonding. Accordingly, the smart IC module includes a plurality of holes. The chip and the metal layer are wire bonded through the holes.

A plating layer for wire bonding can be disposed on the metal layer.

A manufacturing process of the smart IC module can be increased by the plating layer. In addition, the plating layer includes gold (Au). Accordingly, the process cost can be increased.

Therefore, a new structure of a smart IC substrate, a smart IC module, and an IC card that can solve the above problems is required.

### DISCLOSURE

### Technical Problem

An embodiment provides a smart IC substrate with improved reliability.

### Technical Solution

A smart IC substrate according to an embodiment includes a substrate including a first surface and a second surface opposite to the first surface; a bonding layer disposed on the first surface; a metal layer disposed on the bonding layer; and a plating layer disposed on one surface of the metal layer, and wherein the metal layer includes an aluminum (Al)-copper (Cu) alloy or an aluminum (Al)-copper (Cu)-A alloy.

### Advantageous Effects

A smart IC substrate according to an embodiment includes a metal layer. The metal layer includes an alloy. The metal layer includes a plurality of conductive patterns.

The alloy may be a binary alloy or a ternary or higher alloy. Since the metal layer is formed of the alloy, a bonding property and a rigidity of the metal layer are improved. Accordingly, a wire can be directly bonded to the metal layer. Accordingly, a separate plating layer for connecting the chip and the metal layer can be omitted. Accordingly, the process efficiency is improved.

In addition, the plurality of wires are bonded to a same metal layer. Accordingly, the bonding property of the wires can be uniform. Accordingly, the reliability of the smart IC module is improved.

In addition, since the metal layer is formed of the alloy, corrosion resistance and electrical conductivity of the metal layer are improved. Accordingly, a signal between the chip and the conductive pattern can be easily transferred. In addition, a bonding region of the metal layer can be prevented from being oxidized during a process.

### DESCRIPTION OF DRAWINGS

FIG. 1 is a top view of a first surface of a smart IC substrate according to a first embodiment.

FIG. 2 is a top view of a second surface of a smart IC substrate according to a first embodiment.

FIG. 3 is a cross-sectional view taken along region A-A′ of FIG. 2.

FIG. 4 is a top view of a second surface of a smart IC module according to a first embodiment.

FIG. 5 is a cross-sectional view taken along region B-B′ of FIG. 4.

FIG. 6 is a top view of a first surface of a smart IC substrate according to a second embodiment.

FIG. 7 is a top view of a second surface of a smart IC substrate according to a second embodiment.

FIG. 8 is a cross-sectional view taken along region C-C′ of FIG. 7.

FIG. 9 and FIG. 10 are cross-sectional views taken along region D-D′ of FIG. 7.

FIG. 11 is a top view of a second surface of a smart IC module according to a second embodiment.

FIG. 12 is a cross-sectional view taken along region E-E′ of FIG. 11.

FIG. 13 is a cross-sectional view taken along region of FIG. 11.

FIG. 14 is an exploded perspective view of a smart IC card according to an embodiment.

FIG. 15 is a drawing for explaining a combination of a smart IC module according to an embodiment.

### MODES OF THE INVENTION

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and redisposed.

In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art. In addition, the terms used in the embodiments of the present disclosure are for describing the embodiments and are not intended to limit the present disclosure.

In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

Hereinafter, a smart IC substrate, a smart IC module, and a smart IC card according to an embodiment will be described with reference to the drawings.

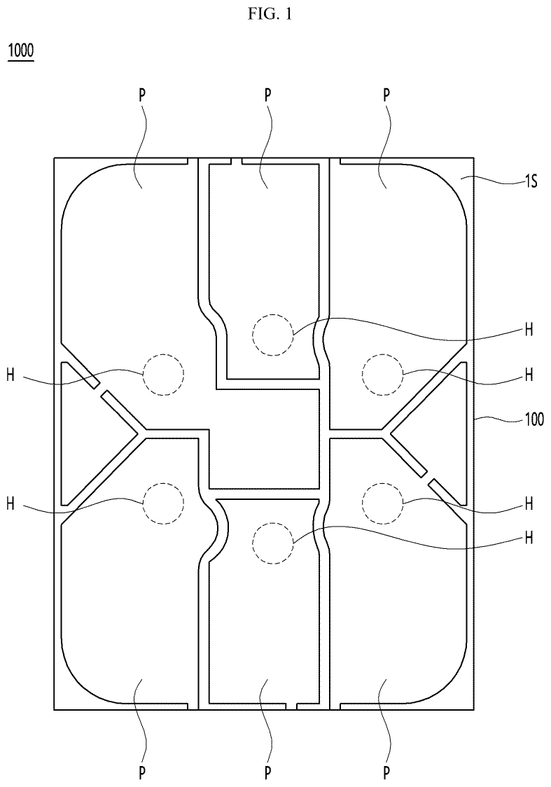

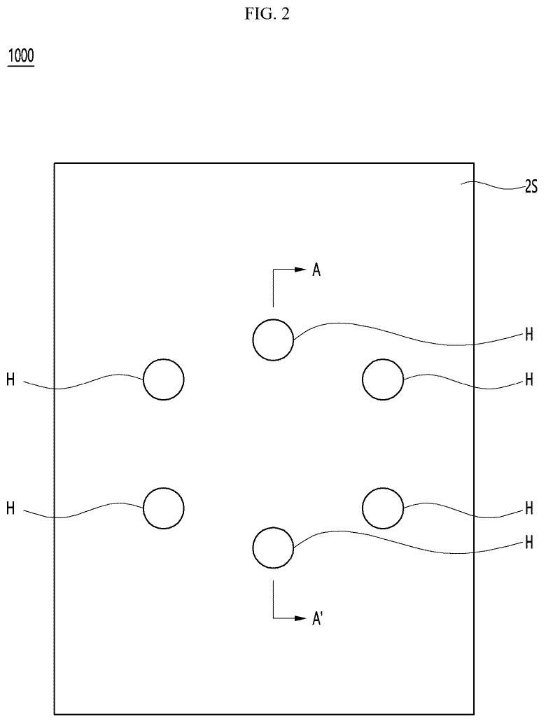

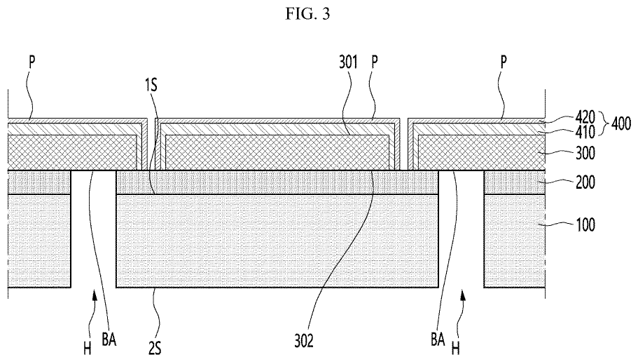

A smart IC substrate 1000 and a smart IC module 2000 according to a first embodiment will be described with reference to FIGS. 1 to 5.

Referring to FIGS. 1 to 3, the smart IC substrate 1000 includes a substrate 100, a bonding layer 200, a metal layer 300, and a plating layer 400.

The substrate 100 includes a first surface 1S and a second surface 2S. The first surface 1S and the second surface 2S are opposite surfaces from each other.

The first surface 1S is a contact surface. In detail, the first surface 1S is a surface that can recognize information of the smart IC module by direct or indirect contact. The second surface 2S is a bonding surface (Bonding Surface). In detail, the second surface 2S is a surface on which a chip is mounted and is bonded to a main body of the IC card.

The substrate 100 includes a resin material. The substrate 100 may include a prepreg including glass fibers. In detail, the substrate 100 may include a material in which glass fibers and silicon-based filler (Si filler) are dispersed inside an epoxy resin.

Alternatively, the substrate 100 may be rigid or flexible. For example, the substrate 100 may include glass or plastic. In detail, the substrate 100 may include chemically strengthened/semi-strengthened glass such as soda lime glass or aluminosilicate glass. Alternatively, the substrate 100 may include polyimide (PI), polyethylene terephthalate (PET), propylene glycol (PPG), polycarbonate (PC), or sapphire.

Alternatively, the substrate 100 may include an optically isotropic film. For example, the substrate 100 may include COC (Cyclic Olefin Copolymer), COP (Cyclic Olefin Polymer), optically isotropic polycarbonate (PC), or optically isotropic polymethyl methacrylate (PMMA).

Alternatively, the substrate 100 may be bent while having a partially curved surface. That is, the substrate 100 may be bent while having a partially flat surface and a partially curved surface. In detail, an end of the substrate 100 may be bent while having a curved surface. Alternatively, the substrate 100 may be bent with a random curvature.

The substrate 100 may have a thickness within a set range. For example, a thickness of the substrate 100 may be 60 μm to 140 μm, 70 μm to 120 μm, or 80 μm to 100 μm. If the thickness of the substrate 100 is less than 60 μm, a support force of the substrate 100 decreases. In addition, when the thickness of the substrate 100 is more than 140 μm, the thickness of the smart IC substrate may increase. Accordingly, a size of the IC card increases.

The substrate 100 has insulating properties. Accordingly, the substrate 100 prevents a short circuit between circuits. In addition, the substrate 100 supports the circuit during a process of forming the circuit.

The substrate 100 includes a hole. In detail, the substrate 100 includes a plurality of holes H.

At least one of the plurality of holes is a region where wire bonding is performed. For example, all of the plurality of holes are regions where wire bonding is performed. Alternatively, some of the plurality of holes are regions where wire bonding is performed. A chip C and a plating layer are wire bonded through the hole H.

The hole H has a width within a set range. The width of the hole H may be a diameter of the hole or a minimum distance between inner surfaces of the hole. For example, the width of the hole H may be 500 μm to 1000 μm, 600 μm to 900 μm, or 700 μm to 800 μm. If the width of the hole H is less than 500 μm, wire bonding becomes difficult. In addition, if the width of the hole H exceeds 1000 μm, the support force of the substrate 100 decreases.

The bonding layer 200 is disposed on the substrate 100. In detail, the bonding layer 200 is disposed on the first surface 1S.

The bonding layer 200 includes a resin material. For example, the bonding layer 200 may include at least one of an epoxy resin, an acrylic resin, and a polyimide resin. In addition, the bonding layer 200 may include at least one additive of natural rubber, a plasticizer, a curing agent, and a phosphorus flame retardant. Accordingly, the flexibility of the bonding layer 200 is improved.

The bonding layer 200 may have a thickness within a set range. For example, a thickness of the bonding layer 200 may be 15 μm to 35 μm, 20 μm to 30 μm, or 22 μm to 28 μm. If the thickness of the bonding layer 200 is less than 15 μm, an adhesive strength of the bonding layer 200 decreases. As a result, the metal layer on the bonding layer 200 may be delaminated. In addition, if the thickness of the bonding layer 200 exceeds 35 μm, the thickness of the smart IC substrate may increase. As a result, the size of the IC card increases.

The metal layer 300 is disposed on the substrate 100. The metal layer 300 is disposed on the bonding layer 200.

The metal layer 300 may have a thickness within a set range. For example, a thickness of the metal layer 300 may be 20 μm to 60 μm, 25 μm to 50 μm, or 35 μm to 40 μm. If the thickness of the metal layer 300 is less than 20 μm, a resistance of the metal layer 300 increases. In addition, if the thickness of the metal layer 300 exceeds 60 μm, the thickness of the smart IC substrate may increase. As a result, the size of the IC card increases. In addition, a process efficiency may decrease.

The metal layer 300 includes a plurality of conductive patterns P. The conductive patterns P are formed by patterning the metal layer 300.

The conductive patterns P are disposed on the first surface 1S. The conductive patterns P are disposed on the contact surface. The conductive patterns P are spaced apart from each other. The holes H are disposed in regions corresponding to each conductive pattern P.

The metal layer 300 includes a metal alloy. For example, the metal layer 300 may include aluminum (Al) and copper (Cu). In detail, the metal layer 300 may include an aluminum (Al)-copper (Cu) alloy. That is, the metal layer 300 may include a binary alloy.

The aluminum and the copper may be contained in a set range. That is, the metal layer 300 may include an alloy. In detail, the metal layer 300 may include an aluminum (Al)-copper (Cu) alloy whose main component is aluminum.

The aluminum may be contained in a content of 70 at % or more. In detail, the aluminum may be contained in a content of 70 at % to 95 at %, 73 at % to 87 at %, or 75 at % to 85 at %. A range of the atomic percent (at %) of the aluminum is based on the atomic percent of the aluminum (Al)-copper (Cu) alloy being 100.

The bonding characteristics of the metal layer are controlled by the aluminum. Since the metal layer includes aluminum in the above range, the bonding strength of the metal layer is improved. Accordingly, the chip can be directly wire bonded to the metal layer 300. Accordingly, an arrangement of a separate plating layer on the other surface 302 of the metal layer can be omitted.

If the aluminum is less than 70 at %, the bonding strength of the metal layer decreases. Accordingly, the connection characteristics of the chip and the metal layer decrease. Therefore, the reliability of the smart IC module decreases.

If the aluminum exceeds 95 at %, the metal layer approaches the characteristics of pure aluminum. Accordingly, the mechanical strength and electrical conductivity of the metal layer are reduced. Therefore, the driving characteristics of the smart IC module are reduced.

The copper may be contained in a content of 30 at % or less. Specifically, the copper may be contained in a content of 5 at % to 30 at %, 7 at % to 20 at %, or 10 at % to 15 at %. The range of the atomic percent (at %) of the copper is based on the atomic percent of the aluminum (Al)-copper (Cu) alloy being 100.

The strength and electrical conductivity of the metal layer are controlled by the copper. Since the metal layer includes the copper in the above range, the strength and electrical conductivity of the metal layer are improved. Accordingly, the chip can prevent cracks from occurring in the metal layer 300 when wire bonding the metal layer. In addition, signals between the chip and the metal layer can be easily transferred.

If the copper is less than 5 at %, the mechanical strength and electrical conductivity of the metal layer are reduced. Accordingly, when connecting the chip and the metal layer, a crack may be formed in the metal layer. Accordingly, the reliability of the smart IC module decreases. In addition, the signal between the chip and the metal layer does not easily move. Accordingly, the driving characteristics of the smart IC module decrease.

If the copper exceeds 30 at %, a solubility limit of the aluminum is exceeded. Accordingly, a formation of the aluminum-copper alloy becomes difficult. Accordingly, the bonding characteristics of the metal layer decrease. Accordingly, the reliability of the smart IC module decreases.

The metal layer 300 may further include another metal. In detail, the metal layer may include a copper-aluminum-A alloy. The A may include at least one metal among nickel (Ni), titanium (Ti), zinc (Zn), tin (Sn), chromium (Cr), molybdenum (Mo), and manganese (Mn). That is, the metal layer 300 may include a ternary alloy or more.

The metal A may be included within a set range. The metal A may be included less than the aluminum. The metal A may be included in a different content than the copper. For example, the metal A may be included more than the copper. Alternatively, the metal A may be included less than the copper.

The aluminum may be contained in a content of 70 at % or more. Specifically, the aluminum may be contained in a content of 70 at % to 90 at %, 73 at % to 87 at %, or 75 at % to 85 at %. A range of the atomic percent (at %) of the aluminum is based on the atomic percent of the aluminum (Al)-copper (Cu)-A alloy being 100.

The copper may be contained in a content of 25 at % or less. Specifically, the copper may be contained in a content of 5 at % to 25 at %, 7 at % to 20 at %, or 10 at % to 15 at %. The range of the atomic percent (at %) of the copper is based on the atomic percent of the aluminum (Al)-copper (Cu)-A alloy being 100.

The metal A may be contained in a content of 10 at % or less. Specifically, the metal A may be contained in a content of 0.1 at % to 10 at %, 3 at % to 9 at %, or 5 at % to 7 at %. The range of the atomic percent (at %) of the metal A is based on the atomic percent of the aluminum (Al)-copper (Cu)-A alloy being 100.

A corrosion resistance of the metal layer 300 is improved by the metal A. If the metal A is less than 0.1 at %, the corrosion resistance of the metal layer 300 may decrease. Accordingly, the reliability of the smart IC module may decrease.

In addition, the rollability of the metal layer 300 is improved by the metal A. The alloy is formed by a rolling process. If the metal A is less than 0.1 at %, the rollability of the metal layer 300 decreases. As a result, a thickness of the metal layer 300 can increase. In addition, a surface roughness of the metal layer 300 can increase.

When the metal A exceeds 10 at %, a secondary phase due to the metal A can be formed during an alloying process. As a result, the composition of the alloy becomes non-uniform. Accordingly, at least one of the bonding properties, strength, corrosion resistance, and rollability of the metal layer can decrease.

The plating layer is disposed on the metal layer 300. In detail, the plating layer is disposed on one surface 301 of the metal layer. The conductive pattern P is formed by the metal layer 300 and the plating layer 400.

The plating layer 400 includes a first layer 410 and a second layer 420. The first layer 410 is in contact with the metal layer 300. The second layer 420 is in contact with the first layer 410. Accordingly, the first layer 410 is disposed between the metal layer 300 and the second layer 420.

Although not shown in the drawing, an organic coating layer may be disposed on the second layer 420. The organic coating layer protects the second layer 420. Accordingly, corrosion of the second layer 420 may be prevented.

The first layer 410 and the second layer 420 may include different metals. In detail, the first layer 410 may include nickel (Ni). The second layer 420 may include gold (Au) or palladium (Pd).

A thicknesses of the first layer 410 and the second layer 420 are different. In detail, the thickness of the first layer 410 is greater than the thickness of the second layer 420. For example, the thickness of the first layer 410 may be 1 μm to 3 μm. The thickness of the second layer 420 may be 0.01 μm to 0.1 μm. The plating layer 410 is disposed on the first surface 1S of the substrate 100. Therefore, the plating layer 400 may be exposed to the outside of the IC card. The first layer 410 includes nickel. As a result, harmful toxicity may be transmitted to an user.

Accordingly, the second layer 420 is disposed on the first layer 410. Accordingly, the first layer 410 is prevented from being exposed to the outside. In addition, the second layer 420 includes gold. Accordingly, corrosion of the first plating layer 410 is prevented. In addition, an aesthetic sense of the user is improved. In addition, the second layer 420 is disposed with a very thin thickness. Accordingly, the process cost is reduced and the process efficiency is improved.

The wire is bonded to the metal layer 300. In detail, the wire is bonded to the other surface 302 of the metal layer. One region of the other surface 302 is exposed by the hole H. That is, the other surface 302 includes a bonding region BA exposed by the hole H. The wire is bonded to the bonding region BA. The wire is in direct contact with the metal layer and bonded with the bonding region BA.

As described above, the metal layer includes an alloy. Accordingly, the adhesive strength and rigidity of the metal layer increase. Accordingly, the wire can be directly bonded with the metal layer.

Accordingly, a separate plating layer disposed on the other surface of the metal layer can be omitted. Accordingly, the process efficiency of the smart IC module can be improved. In addition, a plurality of wires are bonded with a same metal layer 300. When a plurality of plating layers are disposed on the other surface of the metal layer, thicknesses of the plating layers can vary due to errors during the process. Accordingly, the bonding strengths of the plating layers can vary from each other. Accordingly, the bonding strengths of the plurality of wires can vary. Accordingly, a speed of a signal moving to each conductive pattern can become uneven.

However, since a plurality of wires are bonded with a same metal layer 300, the bonding strengths of the plurality of wires can become uniform. Accordingly, the reliability and operating characteristics of the smart IC module can be improved.

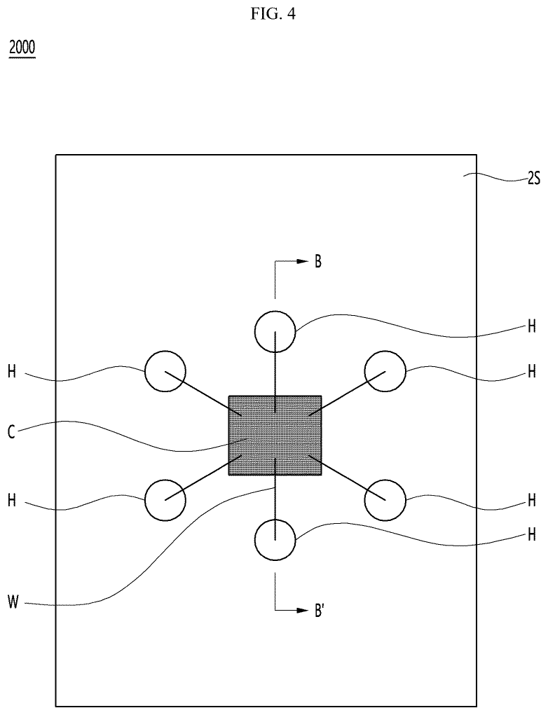

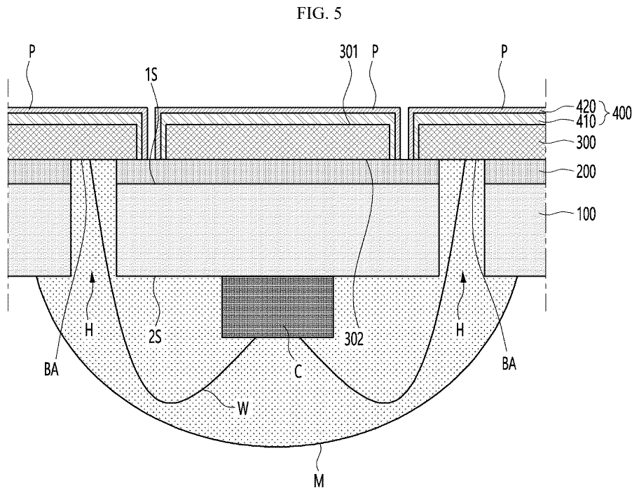

Hereinafter, a smart IC module according to the first embodiment will be described with reference to FIGS. 4 and 5.

Referring to FIGS. 4 and 5, the smart IC module 2000 includes the smart IC substrate 1000 and the chip C described above.

The chip C is disposed on the second surface 2S. In detail, the chip C is disposed on a bonding surface.

The chip C is connected to the metal layer 300. The chip C is in direct contact with the metal layer 300. The chip C is connected to the other surface 302 of the metal layer 300. The chip C is connected to the bonding region BA of the other surface of the metal layer 300. In detail, the chip C and the bonding region BA are wire-bonded by a wire W. Accordingly, the chip C and the conductive pattern P are electrically connected.

The wire W includes a metal. In detail, the wire W may include a same or different material as the metal layer 300. For example, the wire W may include gold, copper, or aluminum.

A molding member M may be disposed on the chip C. The molding member M is disposed while covering the chip C and the wire W. Accordingly, it is possible to prevent wire bonding from being damaged by external impact.

A smart IC substrate according to the first embodiment includes a metal layer including an alloy. The metal layer is patterned to form a plurality of conductive patterns.

The alloy may be a binary alloy or a ternary or higher alloy. Since the metal layer is formed of the alloy, the bonding force and rigidity of the metal layer may be improved. Accordingly, the wire may be directly bonded to the metal layer. Accordingly, a separate plating layer for connecting the chip and the metal layer may be omitted. Accordingly, process efficiency is improved.

In addition, the plurality of wires are bonded with a same metal layer. Accordingly, the bonding properties of the wires can be made uniform. Accordingly, the reliability of the smart IC module can be improved.

In addition, since the metal layer is formed of the alloy, the corrosion resistance and electrical conductivity of the metal layer can be improved. Accordingly, the signal between the chip and the conductive pattern can be easily moved. In addition, the bonding region of the metal layer can be prevented from being oxidized during the process.

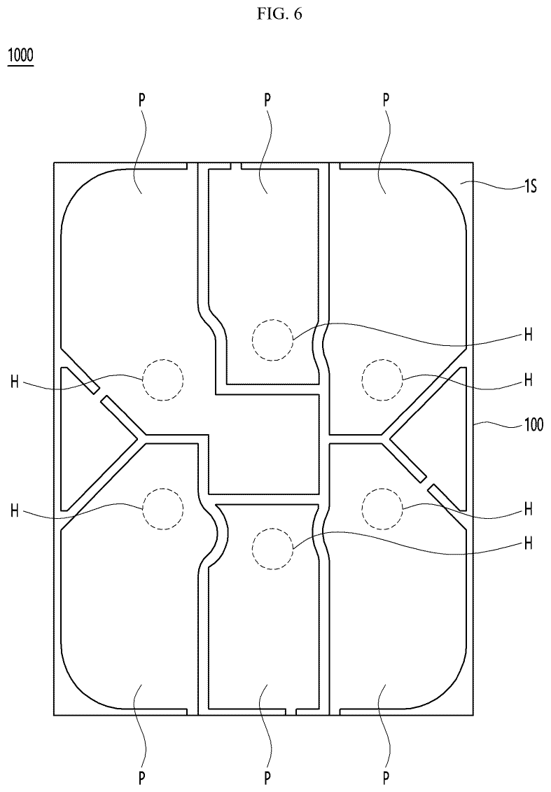

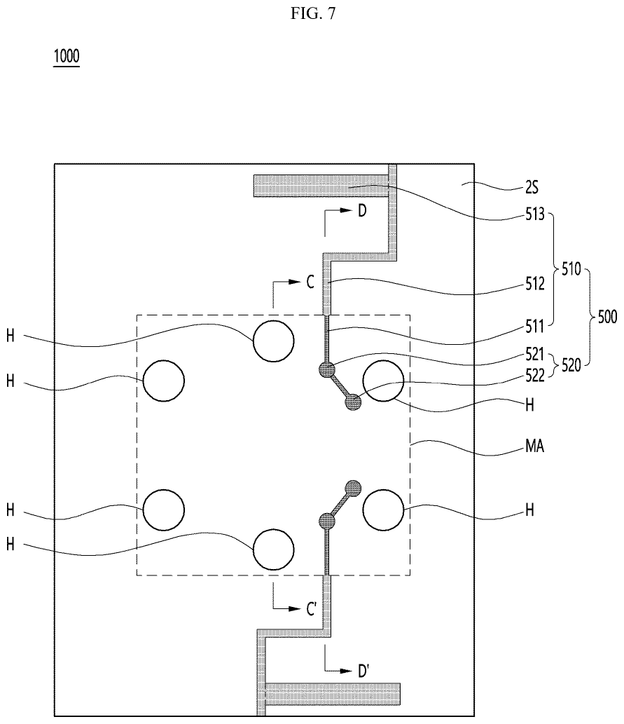

Hereinafter, a smart IC substrate 1000 and a smart IC module 2000 according to the second embodiment will be described with reference to FIGS. 6 to 13.

Referring to FIGS. 6 to 10, the smart IC substrate 1000 includes a substrate 100, a bonding layer 200, a metal layer 300, and a plating layer.

The substrate 100 includes a first surface 1S and a second surface 2S. The first surface 1S and the second surface 2S are opposite surfaces. The first surface 1S is defined as a contact surface. In addition, the second surface 2S is defined as a bonding surface.

The material, shape, and thickness of the substrate 100 are the same as those of the first embodiment.

The substrate 100 includes a hole H. The hole H includes a plurality of holes. At least one of the plurality of holes is a region for wire bonding. For example, all of the plurality of holes are regions for wire bonding. Alternatively, some of the plurality of holes are regions for wire bonding. The chip C and the plating layer are wire bonded through the hole H.

The hole H has a width within a set range. The width of the hole H can be defined as a diameter of the hole or a minimum distance between inner surfaces of the hole. For example, the width of the hole H may be 500 μm to 1000 μm, 600 μm to 900 μm, or 700 μm to 800 μm. If the width of the hole H is less than 500 μm, wire bonding through the hole H becomes difficult. In addition, if the width of the hole H exceeds 1000 μm, the support force of the substrate 100 decreases.

The bonding layer 200 is disposed on the substrate 100. The bonding layer 200 includes a first bonding layer 210 and a second bonding layer 220. The first bonding layer 210 is disposed on the first surface 1S. The second bonding layer 220 is disposed on the second surface 2S.

The material and thickness of the bonding layer 200 are the same as those of the first embodiment.

The metal layer 300 is disposed on the substrate 100. The metal layer 300 includes a first metal layer 310 and a second metal layer 320. The first metal layer 310 is disposed on the first bonding layer 210. The second metal layer 320 is disposed on the second bonding layer 220.

At least one of the first metal layer 310 and the second metal layer 320 may include the alloy described above.

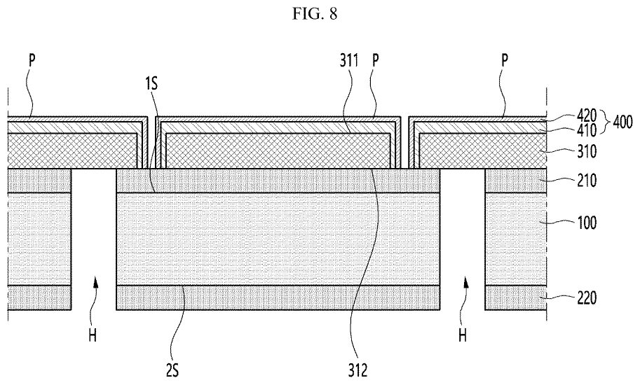

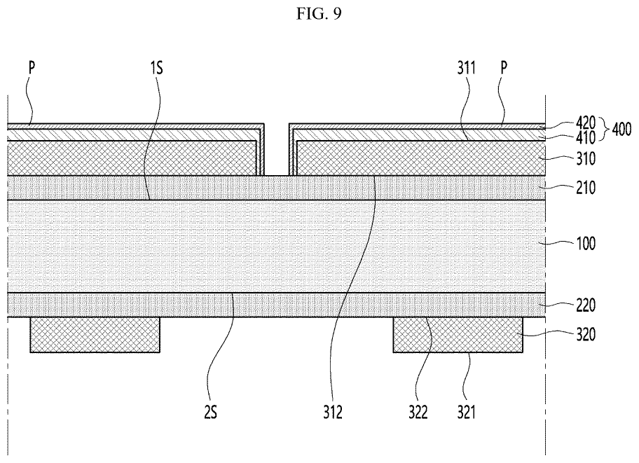

For example, referring to FIGS. 8 and 9, the first metal layer 310 and the second metal layer 320 include the alloy described above. Accordingly, a separate plating layer for wire bonding is not disposed on the other surface 312 of the first metal layer 310. In addition, a separate plating layer for wire bonding is not disposed on one surface 321 of the second metal layer 320.

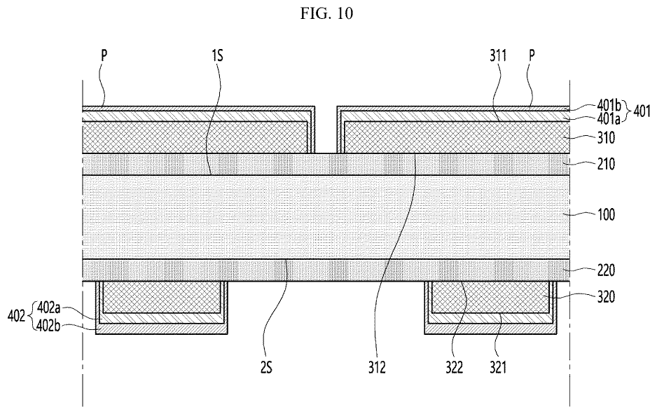

Alternatively, referring to FIGS. 8 and 10, the first metal layer 310 and the second metal layer include different metals. In detail, the first metal layer 310 includes the alloy described above. In addition, the second metal layer 320 may include copper.

Accordingly, a first plating layer 401 is disposed on one surface 311 of the first metal layer 310. In addition, a separate plating layer for wire bonding is not disposed on the other surface 312 of the first metal layer 310. In addition, a separate plating layer for wire bonding is disposed on one surface 321 of the second metal layer 320. In detail, a third plating layer 402 is disposed on one surface 321 of the second metal layer 320.

The first plating layer 401 includes a first-first layer 401a and a first-second layer 401b. In addition, the second plating layer 402 includes a second-first layer 402a and a second-second layer 402b.

The first-first layer 401a and the first-second layer 401b correspond to the above-described first layer 410 and the above-described second layer 420, as previously described.

The second-first layer 402a may include nickel. The second-second layer 402b may include gold or palladium.

The first plating layer 401 and the second plating layer 402 may have different sizes. In detail, a thickness of the first plating layer 401 and a thickness of the second plating layer 402 may be different.

A thickness of the second plating layer 402 is greater than a thickness of the first plating layer 401. The thickness of the first-first layer 401a and the thickness of the second-first layer 402a may be different. In detail, the thickness of the first-first layer 401a may be smaller than the thickness of the second-first layer 402a. In addition, the thickness of the first-second layer 401b and the thickness of the second-second layer 402b may be different. In detail, the thickness of the first-second layer 401b may be smaller than the thickness of the second-second layer 402b. Accordingly, the thickness of the second plating layer 402 is larger than the thickness of the first plating layer 401.

The thickness of the second-first layer 402a may be 2 μm to 9 μm. The thickness of the second-second layer 402b may be 1 μm to 9 μm, 2 μm to 8 μm, or 3 μm to 7 μm. The second plating layer 402 is wire bonded to the chip C. Therefore, the thickness of the second-second layer 402b is greater than the thickness of the first-second layer 401b. If the thickness of the second-second layer 402b is less than 1 μm, the wire is not stably bonded. In addition, if the thickness of the second-second layer 402b is more than 9 μm, the process cost increases and the process efficiency decreases.

The first metal layer 310 includes a plurality of conductive patterns P. The conductive patterns P are formed by patterning the first metal layer 310.

The conductive patterns P are disposed on the first surface 1S. The conductive patterns P are disposed on the bonding layer 200. The conductive patterns P are disposed on the contact surface.

The conductive patterns P are spaced apart from each other. The holes H are disposed in regions corresponding to each conductive pattern P.

The smart IC substrate 1000 includes a wiring pattern 500. The wiring pattern 500 is disposed on the second surface 2S. The wiring pattern 500 is disposed on the second bonding layer 220. The wiring pattern 500 is disposed on the bonding surface.

The wiring pattern 500 is connected to an external antenna pattern. Accordingly, the smart IC module can be driven in a non-contact manner.

The wiring pattern 500 may include a wiring part 510 and a connecting part 520.

The wiring part 510 may include a first wiring part 511, a second wiring part 512, and the third wiring part 513. The first wiring part 511 and the connecting part 520 are disposed inside a molding region MA. The second wiring part 512 and the third wiring part 513 are disposed outside the molding region MA.

The first wiring part 511 and the third wiring part 513 can be connected by the second wiring part 512.

The first wiring part 511, the second wiring part 512, and the third wiring part 513 can have different line widths. For example, the line width of the second wiring part 512 can be larger than the line width of the first wiring part 511. Accordingly, after the molding part M is disposed inside the molding region MA, the wiring part disposed outside the molding part M can be prevented from being damaged.

The line width of the third wiring part 513 may be larger than the line widths of the first wiring part 511 and the second wiring part 512. The third wiring part 513 is a region connected to a card body. Since the line width of the third wiring part 513 is formed large, the smart IC substrate and the card body may be easily connected.

The connecting part 520 may include a first connecting part 521 and a second connecting part 522. In detail, at least one of the plurality of wiring patterns may include the first connecting part 521 and the second connecting part 522.

Sizes of the first connecting part 521 and the second connecting part 522 may be smaller than the size of the hole H. In addition, the size of the second connecting part 522 may be smaller than the size of the third wiring part 513. For example, an area of the second connecting part 522 may be smaller than an area of the third wiring part 513. Accordingly, the space of the chip mounting region can be secured widely, and a packaging size can be reduced.

In addition, the first connecting part 521 or the second connecting part 522 is bonded to the chip by a wire. The connecting part includes two or more connecting parts. Therefore, if a problem occurs in the wire bonding of one connecting part, it can be resolved by wire bonding to another connecting part. For example, if a problem occurs in the wire bonding of the first connecting part 521, additional wire bonding can be performed to the second connecting part 522.

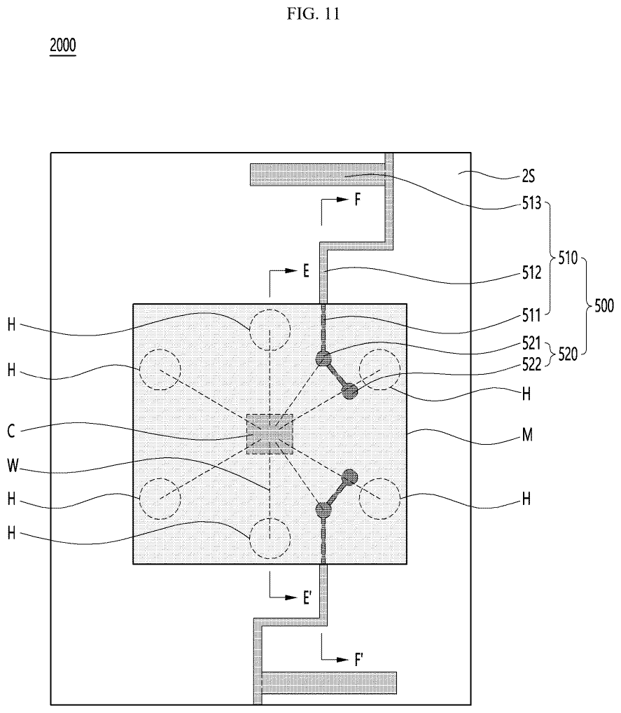

Hereinafter, a smart IC module according to a second embodiment will be described with reference to FIGS. 11 to 13.

Referring to FIGS. 11 to 13, the smart IC module 2000 includes the smart IC substrate 1000 and the chip C described above.

The chip C is disposed on the second bonding layer 220.

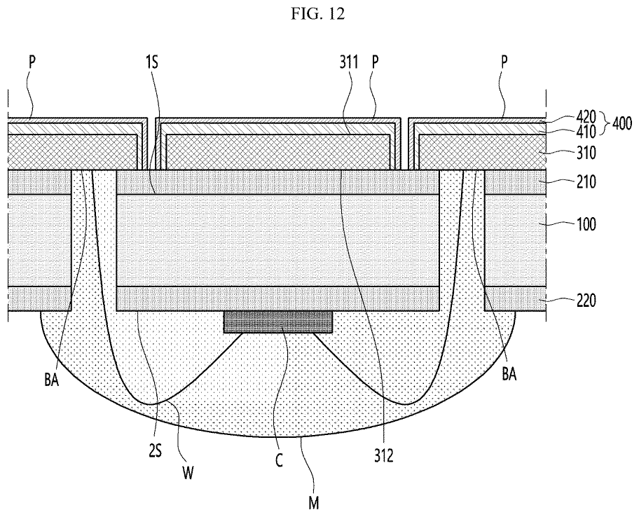

Referring to FIG. 12, the chip C is connected to the first metal layer 310. The chip C is connected to the other surface 312 of the first metal layer 310. The chip C is connected to the bonding region BA of the other surface of the first metal layer 310. In detail, the chip C and the bonding region BA are wire-bonded by a wire W. Accordingly, the chip C and the conductive patterns P are electrically connected.

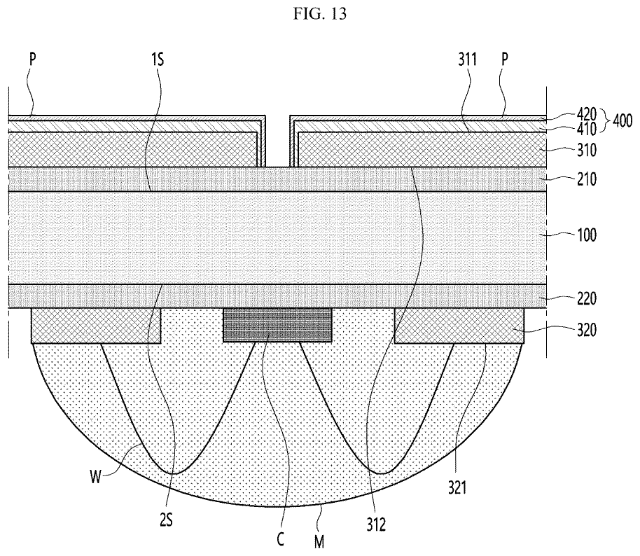

Referring to FIG. 13, the chip C is connected to the second metal layer 320. The chip C is connected to one surface 321 of the second metal layer 320. In detail, the chip C and the second metal layer 320 are wire-bonded by a wire W. Accordingly, the chip C and the antenna patterns are electrically connected.

Alternatively, when a plating layer is disposed on the second metal layer as in FIG. 10, the chip C is connected to the second plating layer 402. In detail, the chip C and the second plating layer 402 are wire-bonded by a wire W. Accordingly, the chip C and the antenna patterns are electrically connected.

The wire W includes a metal. In detail, the wire W may include a material that is the same as or different from the metal layer 300 or the plating layer. For example, the wire W may include gold, copper, or aluminum.

A molding member M may be disposed on the chip C. The molding member M is disposed so as to cover the chip C and the wire W. Accordingly, wire bonding may be prevented from being damaged by external impact.

A smart IC substrate according to the second embodiment includes a metal layer including an alloy. The metal layer is patterned to form a plurality of conductive patterns.

The alloy may be a binary alloy or a ternary or higher alloy. Since the metal layer is formed of the alloy, the bonding property and strength of the metal layer may be improved. Accordingly, the wire may be directly bonded to the metal layer. Accordingly, a separate plating layer for connecting the chip and the metal layer may be omitted. Accordingly, process efficiency is improved.

In addition, the plurality of wires are bonded to a same metal layer. Accordingly, the bonding property of the wires may be uniform. Accordingly, the reliability of the smart IC module can be improved.

In addition, since the metal layer is formed of the alloy, the corrosion resistance and electrical conductivity of the metal layer can be improved. Accordingly, the signal between the chip and the conductive pattern can be easily transferred. In addition, the bonding region of the metal layer can be prevented from being oxidized during the process.

In addition, the first metal layer and the second metal layer can include different metals. The first metal layer can include an alloy. In addition, the second metal layer can include copper. In addition, a second plating layer can be disposed on the second metal layer.

Accordingly, the bonding strength of the first metal layer and the second plating layer is different. For example, the bonding strength of the first metal layer can be greater than the bonding strength of the second plating layer.

The wire connected to the first metal layer is disposed inside the hole. Accordingly, a space limitation occurs when connecting the wire. In addition, a length of the wire can increase. On the other hand, the wire connected to the second metal layer is disposed outside the hole. In addition, the length of the wire may be relatively short.

Accordingly, the bonding force of the wire connected to the first metal layer may be formed to be greater than the bonding force of the wire connected to the second metal layer. Accordingly, the connection characteristics of the wire connected to the first metal layer may be improved.

Hereinafter, the present invention will be described in detail through examples and comparative examples.

### EXAMPLE

The smart IC substrate described above is manufactured.

The metal layer includes the aluminum-copper alloy or the aluminum-copper-A alloy described above. In detail, the metal layer includes the aluminum-copper alloy or the aluminum-copper-A alloy having the atomic percentage ratio described above.

Subsequently, the wire and the metal layer are bonded, and then the bonding force and tensile strength are measured.

### COMPARATIVE EXAMPLE

The smart IC substrate described above is manufactured.

The metal layer includes copper. A plating layer is disposed on the metal layer. The plating layer includes nickel disposed on the metal layer and gold disposed on the nickel.

Next, the wire and the plating layer are bonded, and then the bonding strength and tensile strength are measured.

TABLE 1

| | Embodiment | Comparative Example |
|---|---|---|
| bonding strength (gf) | 5.8 | 4 |
| tensile strength (Mpa) | 1200 | 550 |

Referring to Table 1, it can be seen that the embodiment has greater bonding strength and tensile strength than the comparative example. That is, it can be seen that the metal layer including the alloy has greater bonding strength with the wire. In addition, it can be seen that the strength of the metal layer including the alloy is greater.

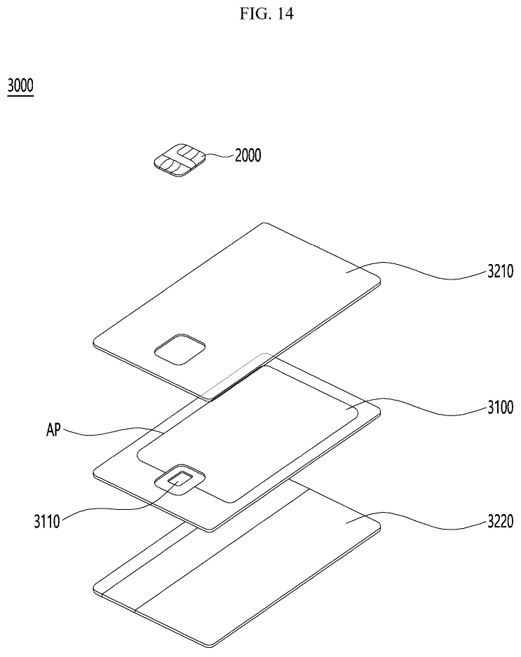

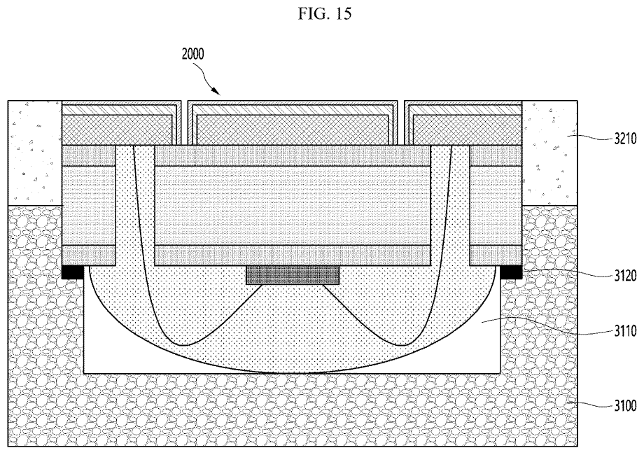

Hereinafter, an IC card according to the embodiment will be described with reference to FIGS. 14 and 15.

Referring to FIGS. 14 and 15, the IC card 3000 may include a main body 3100, an upper layer 3210, and a lower layer 3220.

The main body 3100 includes a receiving portion 3110. The smart IC module 2000 is disposed inside the receiving portion 3110.

The IC card may be driven in various modes. For example, the IC card may be driven as a contact card.

Alternatively, an antenna pattern (AP) may be disposed on the main body 3100. In detail, the antenna pattern may be disposed in a coil shape at an edge of the main body 3100. Accordingly, the IC card may be operated as a contactless card, a combination card, or a hybrid card.

The smart IC module 2000 is inserted into the inside of the receiving portion 3110. The smart IC module 2000 and the main body 3100 are bonded by an adhesive layer 3120. Thus, the smart IC module 2000 is inserted into and fixed in the receiving portion 3110.

The upper layer 3210 is disposed on an upper portion of the main body 3100. The upper layer 3210 may include a transparent material. The upper layer 3210 may include a transparent resin material. The upper layer 3210 may be disposed as at least one layer. That is, the upper layer 3210 may include a plurality of layers.

The lower layer 3220 is disposed at a lower portion of the main body 3100. A magnetic stripe may be disposed on the lower layer 3220. The lower layer 3220 may include a transparent material. The lower layer 3220 may include a transparent resin material. The lower layer 3220 may be disposed as at least one layer. That is, the lower layer 3220 may include a plurality of layers.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1-10. (canceled)

11. A smart IC substrate comprising:
a substrate;
a bonding layer disposed on the substrate;
a metal layer disposed on the bonding layer and including an aluminum alloy; and
a plating layer disposed on the metal layer,
wherein the substrate and the bonding layer include a through hole,
wherein an upper surface and a side surface of the metal layer are covered with the plating layer, and
wherein a lower surface of the metal layer in a region overlapping the through hole in a vertical direction is exposed and provided in the through hole.

12. The smart IC substrate of claim 11, wherein the aluminum alloy includes aluminum having a content of 70 at % to 95 at % and copper having a content of 5 at % to 30 at %.

13. The smart IC substrate of claim 11, wherein the aluminum alloy includes aluminum, copper, and an additional metal, and
wherein the additional metal includes at least one metal among nickel (Ni), titanium (Ti), zinc (Zn), tin (Sn), chromium (Cr), molybdenum (Mo), and manganese (Mn).

14. The smart IC substrate of claim 13, wherein the aluminum is contained in a content of 70 at % to 90 at %,
wherein the copper is contained in a content of 5 at % to 25 at %, and
wherein the additional metal is contained in a content of 0.1 at % to 10 at %.

15. A smart IC module comprising:
a substrate;
a bonding layer disposed on the substrate;
a metal layer disposed on the bonding layer and including an aluminum alloy;
a plating layer disposed on the metal layer;
a chip disposed under the substrate; and
a wire electrically connecting the chip and the metal layer,
wherein the substrate and the bonding layer include a through hole,
wherein an upper surface and a side surface of the metal layer are covered with the plating layer, and
wherein the wire is in direct contact with a lower surface of the metal layer in a region overlapping the through hole in a vertical direction.

16. The smart IC module of claim 15, comprising:
a molding layer for molding the chip,
wherein the molding layer includes a portion disposed within the through hole and in direct contact with a lower surface of the metal layer.

17. A smart IC substrate comprising:
a substrate;
a first bonding layer disposed on the substrate;
a second bonding layer disposed under the substrate;
a first metal layer disposed on the first bonding layer;
a second metal layer disposed under the second bonding layer; and
a first plating layer disposed on the first metal layer,
wherein the substrate and the first bonding layer include a through hole,
wherein an upper surface and a side surface of the first metal layer are covered with the plating layer,
wherein a lower surface of the first metal layer in a region overlapping the through hole in a vertical direction is exposed and provided within the through hole, and
wherein the first metal layer includes an aluminum alloy.

18. The smart IC substrate of claim 17, wherein the aluminum alloy includes aluminum having a content of 70 at % to 95 at % and copper having a content of 5 at % to 30 at %.

19. The smart IC substrate of claim 17, wherein the aluminum alloy includes aluminum, copper, and an additional metal,
wherein the additional metal includes at least one metal among nickel (Ni), titanium (Ti), zinc (Zn), tin (Sn), chromium (Cr), molybdenum (Mo), and manganese (Mn),
wherein the aluminum is contained in a content of 70 at % to 90 at %,
wherein the copper is contained in a content of 5 at % to 25 at %, and
wherein the additional metal is contained in a content of 0.1 at % to 10 at %.

20. The smart IC substrate of claim 17, wherein the first metal layer and the second metal layer include different metal materials.

21. The smart IC substrate of claim 20, comprising:
a second plating layer disposed under the second metal layer.

22. The smart IC substrate of claim 17, wherein the first metal layer and the second metal layer include a same metal material.

23. The smart IC substrate of claim 17, comprising:
a chip disposed under the substrate; and
a wire electrically connecting the chip and the first metal layer,
wherein the wire is in direct contact with the lower surface of the first metal layer in the region overlapping the through hole in the vertical direction.

24. The smart IC substrate of claim 23, comprising:
a molding layer for molding the chip, and
wherein the molding layer includes a portion disposed within the through hole and in direct contact with the lower surface of the first metal layer.

25. The smart IC substrate of claim 24, wherein the first metal layer and the second metal layer include a same metal material,
wherein the wire includes a first wire in direct contact with the lower surface of the first metal layer, and a second wire in direct contact with a lower surface of the second metal layer, and
wherein the molding layer includes a portion in direct contact with the side surface and the lower surface of the second metal layer.
